(19) United States
(12) Patent Application Publication
(10) Pub. No.: US 2023/0186184 A1
(43) Pub. Date: Jun. 15, 2023

(54) ESTIMATED ULTIMATE RECOVERY FORECASTING IN UNCONVENTIONAL RESERVOIRS

(71) Applicant: Saudi Arabian Oil Company, Dhahran (SA)

(72) Inventors: Mustafa A. Basri, Dhahran (SA); Ihab S. Mahmoud Aly, Dhahran (SA); Cenk Temizel, Dhahran (SA)

(21) Appl. No.: 17/546,495

(22) Filed: Dec. 9, 2021

(51) Int. Cl. G06Q 10/04; E21B 41/00; G06N 7/00; G06F 30/28

(52) U.S. Cl. CPC G06Q 10/04; E21B 41/00; G06N 7/005; G06F 30/28; E21B 47/10

(57) ABSTRACT

Disclosed are methods, systems, and computer-readable medium to perform operations including: identifying historical production data related to a plurality of previously-drilled wells; determining, based on the historical production data, a correlation between productivity index and estimated ultimate recovery (EUR); calculating a first productivity index for a current well; and determining, based on the productivity index of the current well and the correlation, a first EUR of the current well.

### TECHNICAL FIELD

The present disclosure applies to estimated ultimate recovery forecasting in unconventional reservoirs.

### BACKGROUND

Estimated ultimate recovery (EUR) forecasting is a challenging task for wells in unconventional shale reservoirs. Legacy techniques typically may not be ideal in these types of wells where very tight rock in the order of nano-Darcy is exploited through long multi-fractured horizontal wells. Specifically, the legacy techniques may not be ideal where desired productivity is achieved by hydraulic fracturing and most of the resultant drainage occurs in the stimulated reservoir volume (SRV). Inappropriate forecasting may result in undesirable use of resources to drill or operate these wells.

### SUMMARY

The present disclosure describes techniques that can be used for forecasting EUR for wells completed in tight/shale reservoirs from short flowback data. Specifically, in embodiments, a productivity index of a well (e.g., instantaneous productivity index value at a 30-day flowback time) may be used as a reference parameter that can be estimated from early-time data. This parameter may have the ability to reflect the future production behavior of the well in terms of cumulative production through proportional comparison of productivity index to EUR.

Aspects of the subject matter described in this specification may be embodied in methods that include the actions of: identifying historical production data related to a plurality of previously-drilled wells; determining, based on the historical production data, a correlation between productivity index and estimated ultimate recovery (EUR); calculating a first productivity index for a current well; and determining, based on the productivity index of the current well and the correlation, a first EUR of the current well.

The previously-described implementation is implementable using a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium. These and other embodiments may each optionally include one or more of the following features.

In some implementations, the first productivity index is an instantaneous productivity index value at a 30-day flowback time.

In some implementations, the first productivity index is calculated using:

$$Productivity Index ( J ) = \frac{Q}{{P}_{e} - {P}_{w f}} ,$$

where J is the first productivity index in stock tank barrel/day/pound per square inch (STB/D/PSI), Q is a surface flowrate at standard conditions in STB/D, Pₑ is an external boundary radius pressure in PSI, and P_{wf} is a well sand-face mid-perf pressure in PSI.

In some implementations, the historical data includes at least one of: historical EUR data of the plurality of previously-drilled wells or historical productivity index data of the plurality of previously-drilled wells.

In some implementations, the method further involves operating the current well based on the first EUR.

In some implementations, identifying, based on the historical production data, a correlation between productivity index and estimated ultimate recovery (EUR) involves: generating, using the historical production data, a numerical model for history matching and forecasting; performing a probabilistic analysis using the numerical model to calculate a predicted EUR; plotting historical productivity index data versus the predicted EUR; and generating a best-fit linear line through the plotted data points.

In some implementations, the probabilistic analysis is performed using a Monte Carlo simulation.

Another aspect of the subject matter described in this specification may be embodied in methods that include the actions of: identifying productivity index data associated with a well; calculating, based on the productivity index data, an estimated ultimate recovery (EUR) of the well; and operating the well based on the predicted EUR of the well.

The previously-described implementation is implementable using a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium. These and other embodiments may each optionally include one or more of the following features.

In some implementations, the methods further involve calculating the EUR of the well based on a correlation of historical productivity index data of at least one other well and a historical EUR of the at least one other well.

In some implementations, the correlation is a linear correlation.

In some implementations, the productivity index data is based on less than five weeks of gas flowback data of the well.

In some implementations, the productivity index is calculated using:

$$Productivity Index ( J ) = \frac{Q}{{P}_{e} - {P}_{w f}} ,$$

where J is the first productivity index in stock tank barrel/day/pound per square inch (STB/D/PSI), Q is a surface flowrate at standard conditions in STB/D, Pₑ is an external boundary radius pressure in PSI, and P_{wf} is a well sand-face mid-perf pressure in PSI.

In some implementations, the productivity index is an instantaneous productivity index value at a 30-day flowback time.

The subject matter described in this specification can be implemented in particular implementations, so as to realize various advantages. For example, embodiments may allow for the incorporation of analysis of several existing wells to create a single correlation that describes the relationship between productivity index of the well and EUR. As such, it may be possible to evaluate EUR of a well from as early as one month of flowback data (other periods of time are also possible). The early evaluation of these wells may expedite critical completion and development decisions that impact project economics. For example, the early evaluation may impact decisions such as number of development wells, spacing between development wells, development wells placement and fracturing job design; including fracture fluid type and volume, proppant type and amount, number of fracture clusters and stages based on the EUR, etc.

The details of one or more implementations of the subject matter of this specification are set forth in the Detailed Description, the accompanying drawings, and the claims. Other features, aspects, and advantages of the subject matter will become apparent from the Detailed Description, the claims, and the accompanying drawings.

### DESCRIPTION OF DRAWINGS

FIG. 1 illustrates an example technique for the generation and use of a model that correlates a productivity index of a well to an estimated ultimate recovery of the well, in accordance with various embodiments.

FIG. 2 illustrates an example log-log plot of gas normalized rate versus gas material balance time, in accordance with various embodiments.

FIG. 3 illustrates an example plot of gas normalized pressure versus the square root of gas material balance time, in accordance with various embodiments.

FIG. 4 illustrates an example compound linear flow type curve, in accordance with various embodiments.

FIG. 5 illustrates an example numerical model history-match, in accordance with various embodiments.

FIG. 6 illustrates an example numerical model forecast, in accordance with various embodiments.

FIG. 7 illustrates an example probabilistic analysis results, in accordance with various embodiments.

FIG. 8 illustrates a productivity index versus time plot for one or more wells, in accordance with various embodiments.

FIG. 9 illustrates an example correlation of productivity index of a well with estimated ultimate recovery, in accordance with various embodiments.

FIG. 10 illustrates an example of estimating ultimate recovery for a new well using its productivity index, in accordance with various embodiments.

FIG. 11 illustrates an example technique for calculating an estimated ultimate recovery of a well, in accordance with various embodiments.

FIG. 12 illustrates another example technique for calculating an estimated ultimate recovery of a well, in accordance with various embodiments.

FIG. 13 illustrates a block diagram of an example computer system used to provide computational functionalities associated with described algorithms, methods, functions, processes, flows, and procedures as described in the present disclosure, in accordance with various embodiments.

Like reference numbers and designations in the various drawings indicate like elements.

### DETAILED DESCRIPTION

The following detailed description describes techniques for forecasting EUR based on flow capacity of a well. Various modifications, alterations, and permutations of the disclosed implementations can be made and will be readily apparent to those of ordinary skill in the art, and the general principles defined may be applied to other implementations and applications, without departing from scope of the disclosure. In some instances, details unnecessary to obtain an understanding of the described subject matter may be omitted so as to not obscure one or more described implementations with unnecessary detail and inasmuch as such details are within the skill of one of ordinary skill in the art. The present disclosure is not intended to be limited to the described or illustrated implementations, but to be accorded the widest scope consistent with the described principles and features.

In line with the discussion above, production forecasting, or EUR (Estimated Ultimate Recovery), is a challenging task in Unconventional Shale Reservoirs. Considering the relatively-higher cost of the wells and operations, it is important to forecast the EUR at very early stages of the production. However, conventional methods do not apply to unconventional shale reservoirs. Thus, evaluating EUR and production forecasting in multi-frac horizontal wells completed in unconventional shale reservoirs during early exploration and appraisal stages is very challenging.

Disclosed herein are methods and systems for calculating an estimated ultimate recovery (EUR) for such wells based on limited data (e.g., an amount of data less than what is used in conventional methods). The limited data may refer to data gathered during a particular period, e.g., a gas flowback period. In some embodiments, the methods and systems use a correlation between a productivity index calculated during early stages of gas flowback (e.g., during the first 3-4 weeks of gas flowback) and EUR. These correlations may be used to evaluate new wells (e.g., multi-frac horizontal wells in an unconventional reservoir) using data during early flowback and before connecting them to a production facility. A productivity index (PI) of a well is a mathematical representation of the ability of a reservoir to deliver fluids to the wellbore.

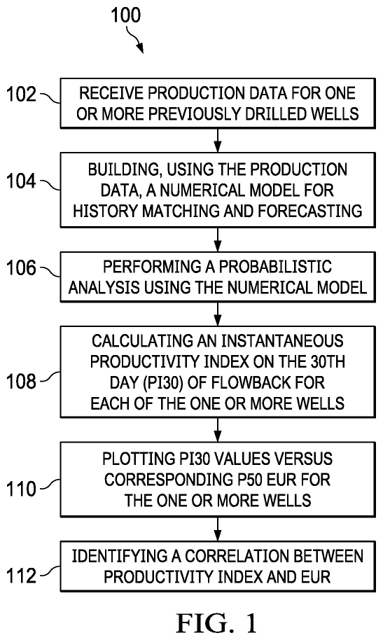

FIG. 1 illustrates an example technique 100 for generating and using a model that correlates a productivity index to EUR, in accordance with various embodiments.

At 102, the technique 100 involves receiving production and/or stimulation data for one or more previously drilled wells. The one or more previously drilled wells may be wells that include characteristics that are similar to one or more wells to be analyzed. For example, the previously drilled wells may be in a same general area as the one or more wells to be analyzed. Additionally or alternatively, the previously drilled wells may be wells that are not in the same general area, but are located in similar geological formations (e.g., the same type of rock, rock with similar porosity values, etc.).

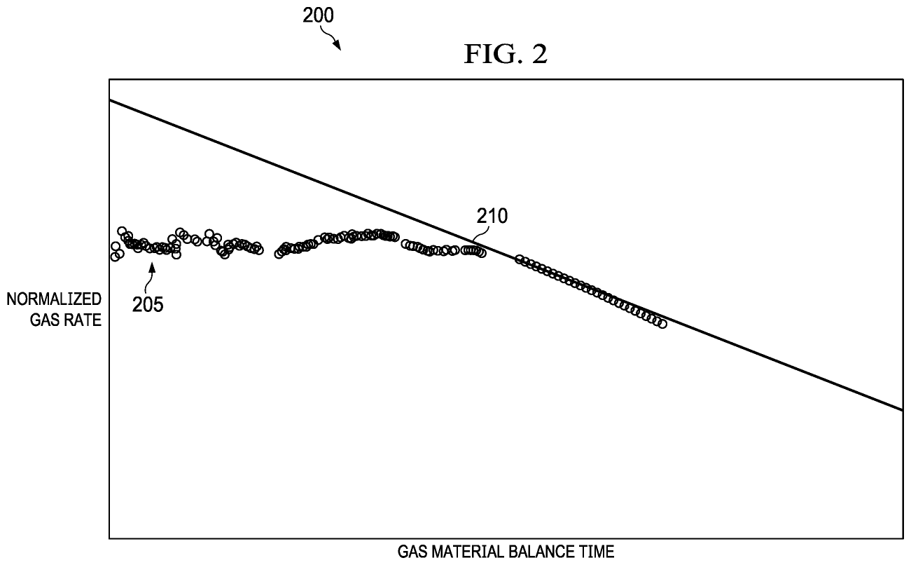

At 104, the technique 100 involves building, using the production data, a numerical model that matches historical data and that can be used to create a forecast. Building the numerical model based on the production data involves a rate transient analysis (RTA) and a production data analysis. FIGS. 2-7, described in more detail below, illustrate examples of the analyses that are performed to build the numerical model.

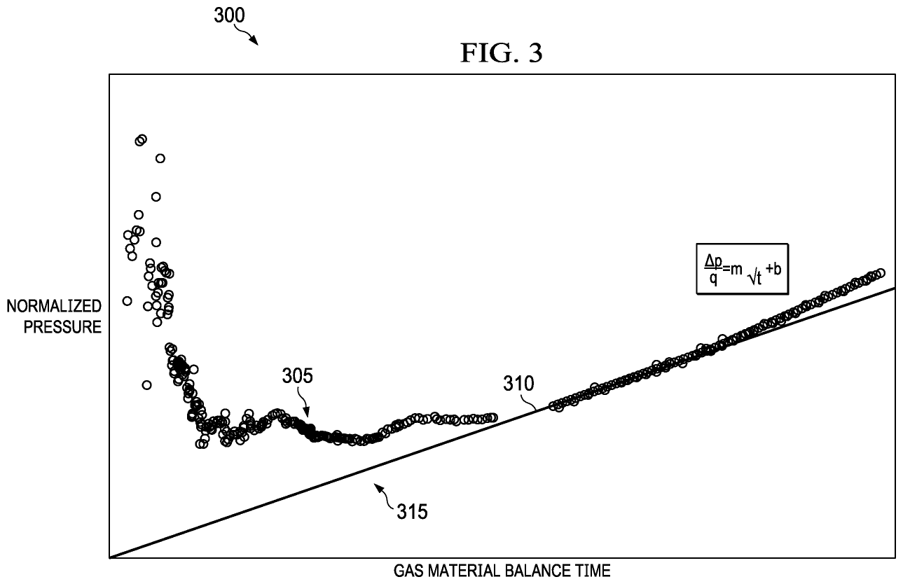

FIGS. 2-3 illustrate examples of data related to the previously drilled wells that are be used to calculate the flow capacity for the one or more wells as described with respect to element 104. The analysis in one or more of FIGS. 2-3 may be performed, for example, for each of the one or more wells identified at 102.

Specifically, FIG. 2 illustrates an example log-log plot 200 of gas normalized rate versus gas material balance time, in accordance with various embodiments. The Y axis depicts normalized gas rate, and the X-axis depicts gas material balance time. Note that the plot is a logarithmic plot. In some embodiments, the plot 200 is used to identify gas flow regimes. After initial well cleanup, the flow regime for a multi-fracture horizontal well completed in an unconventional shale reservoir is expected to be a linear flow. The data points at 205 depict the normalized gas rate over time, and then the point at 210 depicts the start of linear flow. In plot 200, the linear flow regime may be identified by a negative ½ slope line in the log-log plot.

FIG. 3 illustrates an example plot 300 of gas normalized pressure versus the square root of gas material balance time, in accordance with various embodiments. Specifically, FIG. 3 depicts a plot of gas normalized pressure along the Y axis versus the square root of gas material balance time along the X axis. Similarly to FIG. 2, the data points 305 depict the normalized gas pressure, which become linear at 310. The slope 315 of the linear portion of the data yields gas flow capacity Ac\sqrt{k}. In the example of FIG. 3,

$$A c \sqrt{k} = \frac{630.8 T}{m} * \frac{1}{\sqrt{{( ∅ {μ}_{g} {C}_{t} )}_{i}}} ,$$

where m represents the slope of the square root-time plot, T represents the temperature of the reservoir, Ø represents the porosity of the reservoir, μ_{g} represents the viscosity of the gas, and Cₜ represents the total compressibility of the gas. More generally, Ac represents the area of flow of the material (either water or gas), and k represents the permeability value of the material.

As described, FIG. 2 is used to diagnose a linear flow regime. FIG. 3 is used to calculate flow capacity, Ac\sqrt{k}. These also utilized to obtain an initial estimate or guess of reservoir geometry to be used in the numerical modeling (described in more detail below).

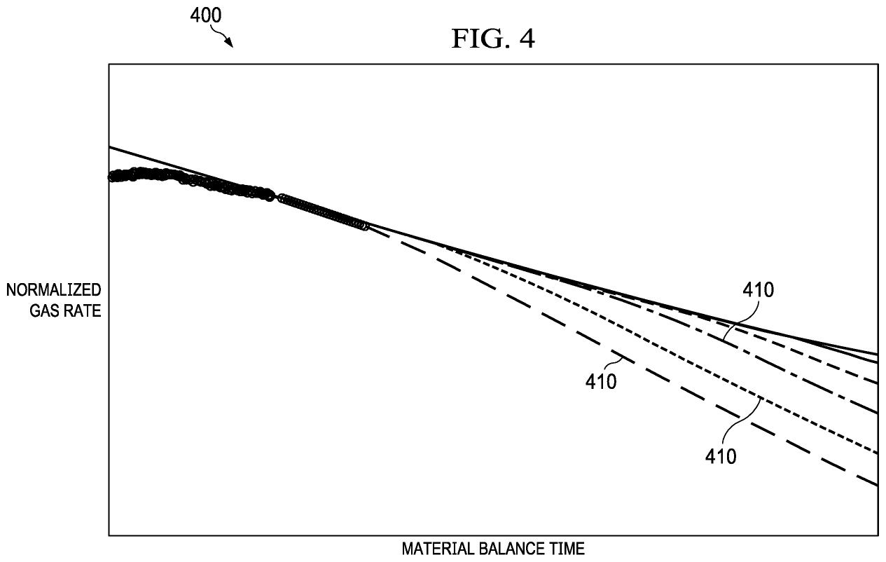

FIG. 4 illustrates an example compound linear flow type curve 400, in accordance with various embodiments. In FIG. 4, the Y axis represents the normalized gas rate, and the X axis represents the material balance time. Note that both the X and Y axes are depicted on a logarithmic scale.

Generally, the compound linear flow type curve may be used to obtain estimates for fracture parameters such as the fracture half-length (x_{f}), stimulated reservoir volume (SRV) permeability (k_{SRV}), and the width of the stimulated zone (xᵢ). These parameters may be seeded to a deterministic model, as described below, to match historical data and create a forecast of the EUR. Note that the forecasted solution may be considered to be non-unique, as the historical data may match on several lines (e.g., lines 410). That is, the historical data is matched to oil production rates, gas production rates, water production rates, and bottom-hole flowing pressures data.

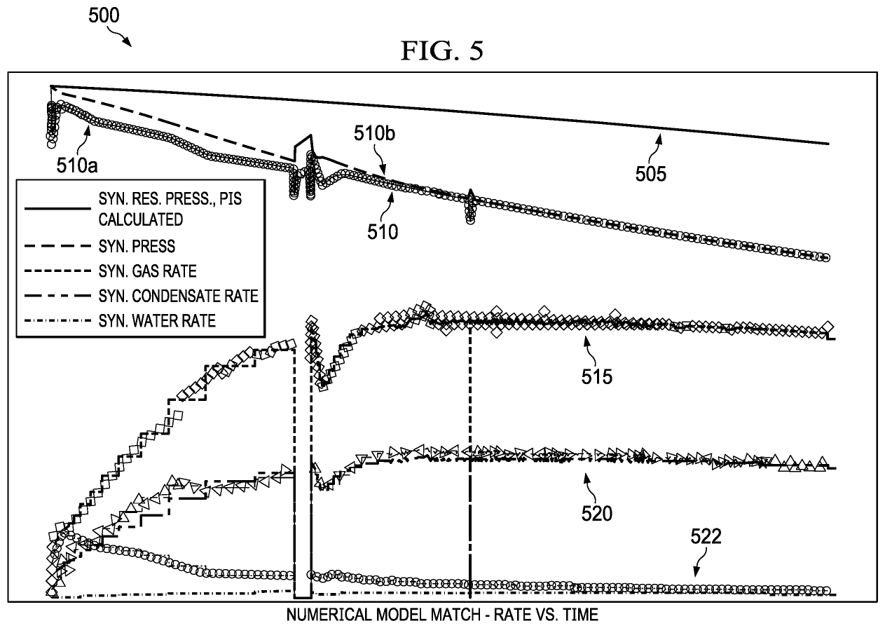

FIG. 5 illustrates an example numerical model history match 500, in accordance with various embodiments. Specifically, the model 500 may be generated using one or more of reservoir input data, pressure-volume-time (PVT) data, and the fracture parameters described above with reference to FIG. 4. Specifically, the fracture parameters may be used as initial parameters that are iterated upon to achieve a match to historical data. The Y axis of the model 500 relates to gas, condensate, and water flow rates and pressure, and the X axis of the model 500 relates to time.

As can be seen in FIG. 5, the model 500 may depict both historical data and synthesized data that is matched to the historical data based on the parameter iteration. For example, line 510 relates to well bottom-hole flowing pressure. The bottom-hole flowing pressure 510 may depict historical data at 510a, and synthesized data 510b that is based on the above-described parameters. As noted, the parameters upon which the synthesized data 510b is based are iterated until the synthesized data 510b generally aligns with the historical data 510a as shown in the model 510. The model 500 may further depict gas flow rate at 515, condensate flow rate at 520, water flow rate at 525, and synthesized reservoir pressure at 505. Note that the various other depictions at 515, 520, and 525 include both depictions of both synthesized and historical data, however such data is not separately enumerated for the sake of clarity of FIG. 5.

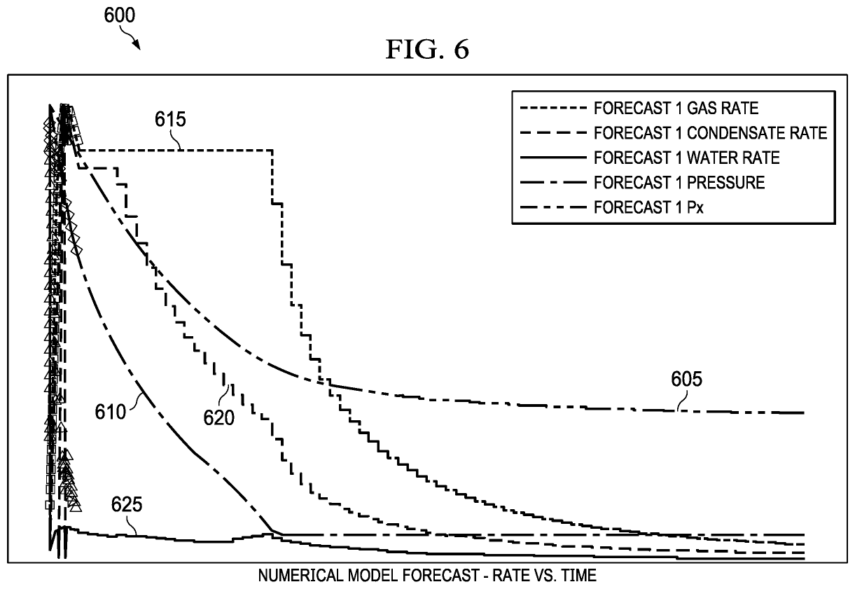

FIG. 6 illustrates an example numerical model forecast 600, in accordance with various embodiments. Specifically, once model 500 is generated and the match of the synthesized parameters to the historical data is performed, the model 500 of FIG. 5 may be used to forecast future parameters as shown in the model 600 of FIG. 6. In embodiments, the model 600 may be constrained by various parameters of the well upon which the parameters are based. Such parameters may include, for example, a maximum gas rate of the well, a minimum bottom hole flowing pressure, an abandonment rate, or some other parameter. Several of the parameters described with respect to the model 500 may then be forecast in model 600. For example, model 600 depicts a forecasted gas flow rate 615, a forecasted condensate flow rate 620, a forecasted water flow rate 625, a forecasted bottom-hole flowing pressure 610, and a forecasted reservoir pressure 605, which may respectively correspond to element 515, 520, 525, 510, and 505 of model 500.

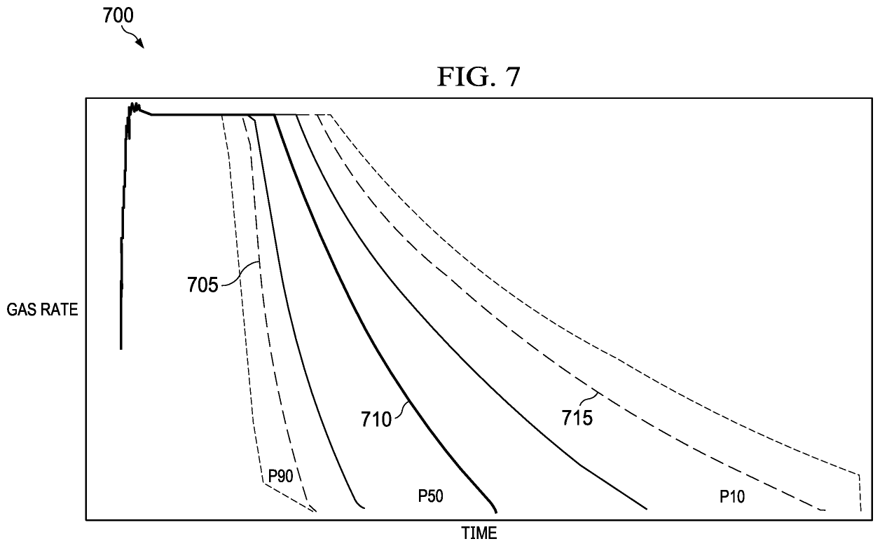

Returning to FIG. 1, the technique 100 then involves running, at 106, a probabilistic analysis. FIG. 7 illustrates an example probabilistic analysis 700, in accordance with various embodiments. Specifically, in FIG. 7, the Y axis depicts gas flow rate, while the X axis depicts time. One example of such a probabilistic analysis is a Monte Carlo simulation. A Monte Carlo simulation may be considered to be a simulation that performs a function based on a number of parameters that are varied to provide a given outcome. The function is re-run multiple times while the parameters are varied, and then the outcomes provide a probability distribution.

For the analysis 700 of FIG. 7, for each individual well uncertainties in reservoir and fracture parameters are assessed to estimate the possible range of EUR. Such parameters may include the fracture half-length (x_{f}), the number of effective fractures (n_{f}), the fracture height (h_{f}), reservoir porosity (ø), and initial water saturation (S_{wi}). Additional or alternative parameters may include dimensionless fracture conductivity (F_{CD}), SRV permeability (k_{SRV}), matrix permeability (kₘₐₜᵣᵢₓ), and width of stimulated zone (xᵢ).

The variance of the factors may provide a depicted analysis such as analysis 700. The analysis 700 may depict different percentile lines for the EUR and production forecast profiles such as a P90 line (which indicates that 90% of results will be more than the depicted line) 705, a P50 line (which indicates that 50% of the results will be more than the depicted line) 710, and a P10 zone (which indicates that 10% of the results will be more than the depicted line) 715. As such, the probabilistic analysis is constrained by reservoir properties ranges and historical data and is run to create P90, P50 and P10 EUR.

Returning to FIG. 1, the technique 100 then involves calculating, at 108, an instantaneous productivity index on the 30^{th} day (PI30) of flowback for each of the one or more wells as described with respect to element 104.

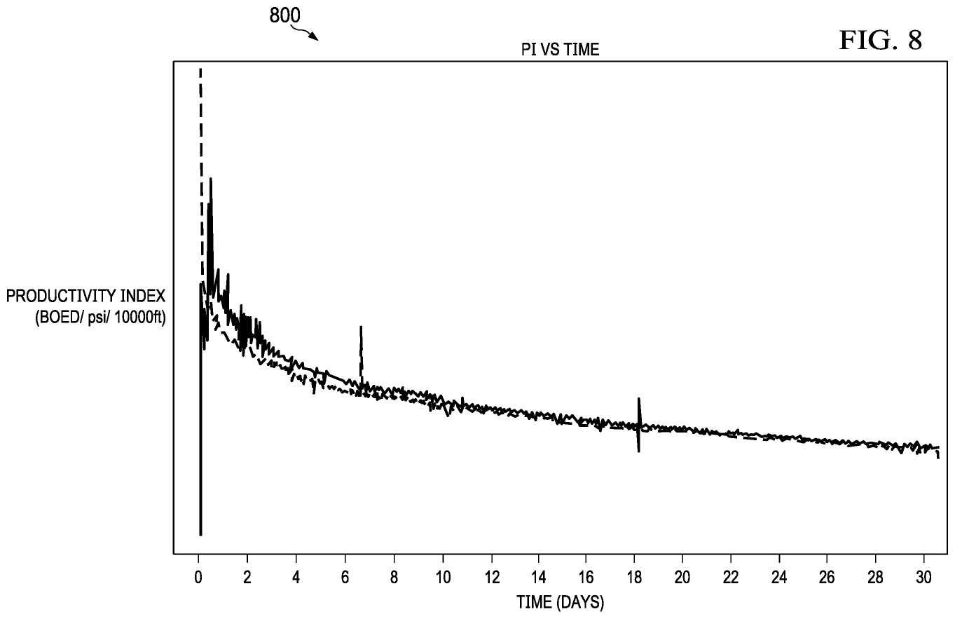

FIG. 8 illustrates a productivity index versus time plot 800 for one or more wells, in accordance with various embodiments. More specifically, the plot 800 is for two multi-fractured horizontal wells completed in a shale reservoir. Here, a productivity index (as defined in Equation [1] below) is used to represent well productivity. PI is also normalized to the 1000-ft interval of lateral length. As shown in the plot 800, PI begins to stabilize at around 30 days of flowback.

$$Productivity Index ( J ) = \frac{Q}{{P}_{e} - {P}_{w f}} \qquad [ 1 ]$$

In Equation [1], J=productivity index in stock tank barrel/clay/pound per square inch (STB/D/PSI), Q=surface flowrate at standard conditions in STB/D, Pₑ=External boundary radius pressure in PSI, and P_{wf}=well sand-face mid-perf pressure in PSI.

The technique 100 may then involve, at 110, plotting PI30 values versus corresponding P50 EUR for the one or more wells. The technique 100 may then include identifying, at 112, a correlation between productivity index and EUR, perhaps using a best fit line through linear regression.

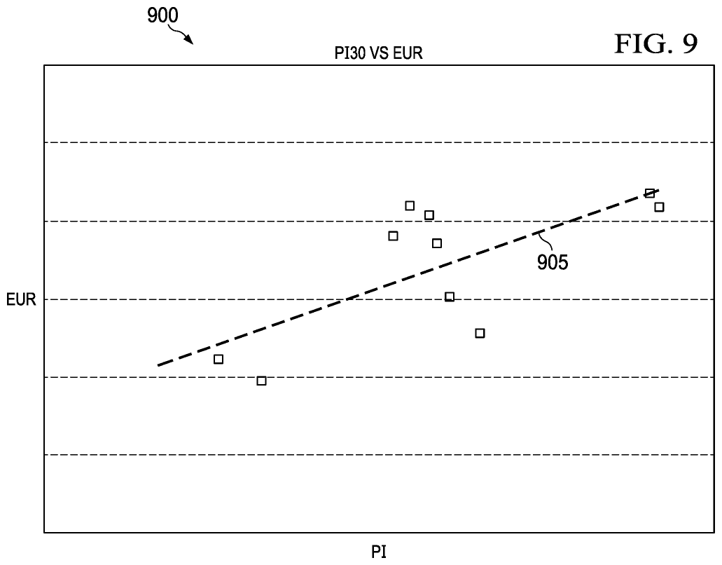

FIG. 9 illustrates an example correlation 900 of productivity index with EUR, in accordance with various embodiments. Specifically, as a measure for productivity, it may be implicit that is productivity index correlated to EUR. The example 900 depicts such a correlation, where the Y axis depicts EUR while the X axis depicts 30-day productivity index. As may be seen, line 905 depicts best fit obtained through linear regression at 112. In embodiments, this straight-line relationship may be used to evaluate new wells, provided that linear flow of that well has been established.

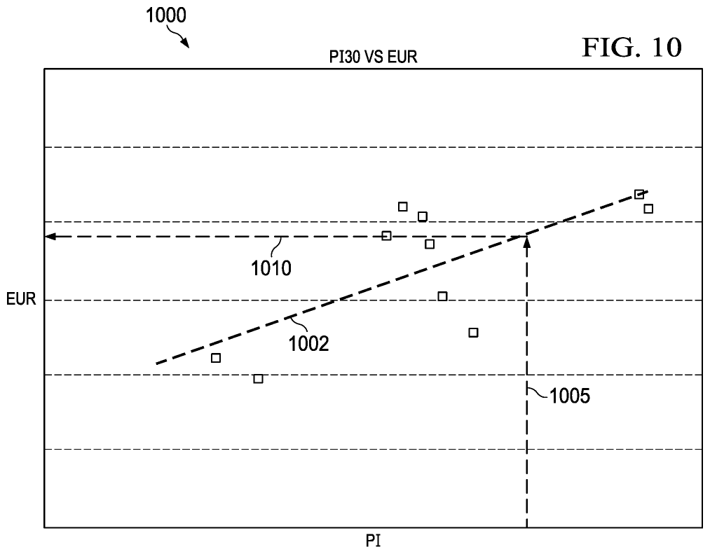

FIG. 10 illustrates an example 1000 of estimating EUR for a new well using its estimated productivity index. Such productivity index may be based on, for example, instantaneous PI at the 30^{th} day of flow back. Using a correlation 1002, line 1005 depicts the estimated productivity index of the new well, going vertically from X axis until intercepts with the best fit line. Line 1010 then depicts the estimated EUR of the new well, moving horizontally, from interception point with best fit line, towards Y axis to read the EUR for the new well.

A workflow to estimate EUR from multi-frac horizontal wells completed in unconventional shale reservoirs was described. The workflow integrates RTA, numerical modeling, and probabilistic analysis. The workflow is designed to estimate EUR for wells completed in unconventional reservoirs during the early phases of development, where there is no production facility to handle produced hydrocarbons and flow back period is limited to cleanup only. The workflow to predict EUR, for multi-frac horizontal wells completed in a shale reservoir, from early-time flow back data. A relationship between Productivity Index (PI), estimated during the early weeks of flowback and EUR was established. This relationship can be harnessed to evaluate the EUR for wells that have 30 days of flowback duration. The workflow utilizes the calculated PI at thirtieth day (PI30) to predict EUR.

The superiorities of the disclosed workflow over the existing techniques include: (1) taking into consideration numerous wells analyses to establish a single correlation that outlines the relationship between PI30 and EUR, (2) the ability to evaluate well EUR from a simple correlation that only use flow rate measurements and bottom-hole pressures during flowback. Further, the early evaluation of these wells will enhance and accelerate key completion and development decisions, which will impact project economics.

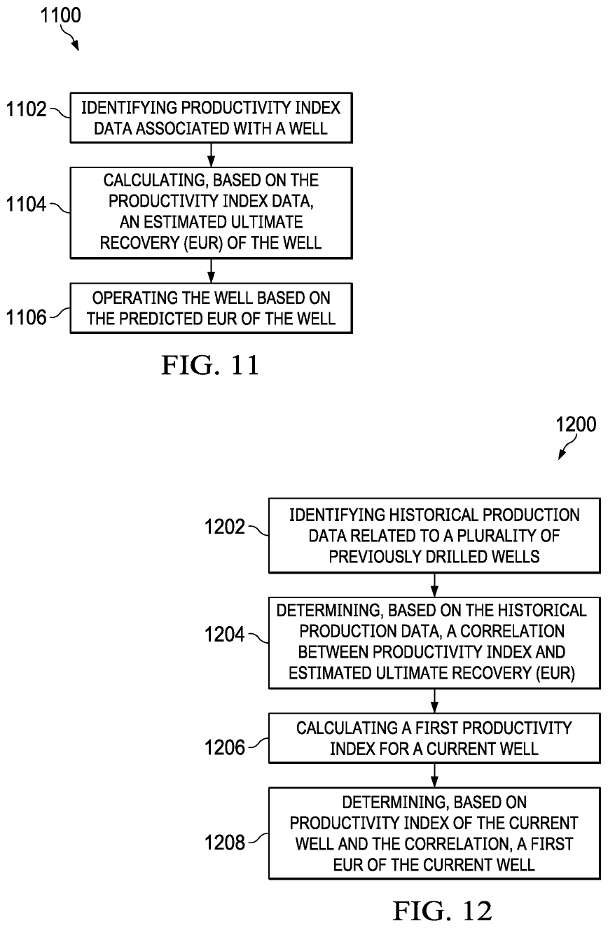

FIG. 11 illustrates an example technique 1100 for prediction of EUR of a well, in accordance with various embodiments. The technique includes identifying, at 1102, productivity index data associated with a well. The data may be based on, for example, flowback data of the well as described above. In some embodiments, the flowback data may be between four and six weeks of gas flowback data of the well.

The technique 1100 further includes predicting, at 1104 based on the productivity index data, an estimated ultimate recovery (EUR) of the well. Such a prediction may be based on a correlation between the productivity index and the EUR of the well as described above with respect to, for example, FIG. 9.

The technique 1100 further includes, operating, at 1106, the well based on the predicted EUR of the well. In some embodiments, the operation may include updating well completion and field development plan models. In some embodiments, the operation may include modifying and/or adjusting such plan models by altering, for example, the number of development wells, the spacing between development wells, or development wells placement and fracturing job design. In some embodiments, the operation may include identifying parameters related to further use of the well, optimizing parameters related to operation of the well (e.g., fracture fluid type and volume, proppant type and amount, number of fracture clusters and stages, etc).

FIG. 12 illustrates an alternative example technique 1200 for prediction of EUR of a well, in accordance with various embodiments.

The technique 1200 includes identifying, at 1202, historical production data related to a plurality of previously-drilled wells. Such historical data may be, for example, EUR or productivity index of the at least one other well. Such identification may be similar to that described above with respect to elements 102 or 104.

The technique 1200 further includes determining, at 1204 based on the historical production data, a correlation between productivity index and estimated ultimate recovery (EUR). Such a correlation may be similar to the correlation described above with respect to, for example, FIG. 9.

The technique 1200 further includes calculating, at 1206, a first productivity index for a current well. Such identification may be based on, for example, instantaneous PI at the 30^{th} day of flow back, as described above.

The technique 1200 further includes determining, at 1208 b based on the productivity index of the current well and the correlation, a first EUR of the current well. Particularly, the EUR may be predicted by comparing the identified productivity index of the well to the correlation described with respect to FIG. 9.

The technique 1200 further includes, based on the determined EUR, updating well completion strategy and field development plan and modify and adjust if necessary.

In some implementations, the first productivity index is an instantaneous productivity index value at a 30-day flowback time.

In some implementations, the first productivity index is calculated using:

$$Productivity Index ( J ) = \frac{Q}{{P}_{e} - {P}_{w f}} ,$$

where J is the first productivity index in stock tank barrel/day/pound per square inch (STB/D/PSI), Q is a surface flowrate at standard conditions in STB/D, Pₑ is an external boundary radius pressure in PSI, and P_{wf} is a well sand-face mid-perf pressure in PSI.

In some implementations, the historical data includes at least one of: historical EUR data of the plurality of previously-drilled wells or historical productivity index data of the plurality of previously-drilled wells.

In some implementations, the method further involves operating the current well based on the first EUR.

In some implementations, identifying, based on the historical production data, a correlation between productivity index and estimated ultimate recovery (EUR) involves: generating, using the historical production data, a numerical model for history matching and forecasting; performing a probabilistic analysis using the numerical model to calculate a predicted EUR; plotting historical productivity index data versus the predicted EUR; and generating a best-fit linear line through the plotted data points.

In some implementations, the probabilistic analysis is performed using a Monte Carlo simulation.

It will be recognized that the above description of FIGS. 1-12 is intended as an example to provide discussion of various concepts herein. The specific variables, time frames, or numerical representations used are provided for the sake of discussion, and other embodiments may vary. For example, in some embodiments the variables used for different measurements or correlations may be different than described above. Additionally, certain measurements may be taken over longer or shorter time frames than described above, for example based on the data collected or the amount or type of historical data used.

The techniques of FIGS. 1-12 can be performed, for example, by any suitable system, environment, software, and hardware, or a combination of systems, environments, software, and hardware, as appropriate. In some implementations, various elements of the techniques of FIGS. 1-12 can be run in parallel, in combination, in loops, or in any order.

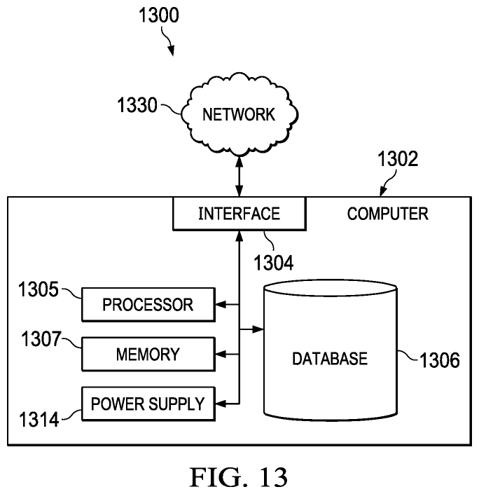

FIG. 13 illustrates a block diagram of an example computer system 1300 used to provide computational functionalities associated with described algorithms, methods, functions, processes, flows, and procedures described in the present disclosure, according to some implementations of the present disclosure. The illustrated computer 1302 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 1302 can include input devices such as keypads, keyboards, and touch screens that can accept user information. Also, the computer 1302 can include output devices that can convey information associated with the operation of the computer 1302. The information can include digital data, visual data, audio information, or a combination of information. The information can be presented in a graphical user interface (UI) (or GUI).

The computer 1302 can serve in a role as a client, a network component, a server, a database, a persistency, or components of a computer system for performing the subject matter described in the present disclosure. The illustrated computer 1302 is communicably coupled with a network 1330. In some implementations, one or more components of the computer 1302 can be configured to operate within different environments, including cloud-computing-based environments, local environments, global environments, and combinations of environments.

At a top level, the computer 1302 is an electronic computing device operable to receive, transmit, process, store, and manage data and information associated with the described subject matter. According to some implementations, the computer 1302 can also include, or be communicably coupled with, an application server, an email server, a web server, a caching server, a streaming data server, or a combination of servers.

The computer 1302 can receive requests over network 1330 from a client application (for example, executing on another computer 1302). The computer 1302 can respond to the received requests by processing the received requests using software applications. Requests can also be sent to the computer 1302 from internal users (for example, from a command console), external (or third) parties, automated applications, entities, individuals, systems, and computers.

Each of the components of the computer 1302 can communicate using a system bus 1303. In some implementations, any or all of the components of the computer 1302, including hardware or software components, can interface with each other or the interface 1304 (or a combination of both) over the system bus 1303. Interfaces can use an application programming interface (API) 1312, a service layer 1313, or a combination of the API 1312 and service layer 1313. The API 1312 can include specifications for routines, data structures, and object classes. The API 1312 can be either computer-language independent or dependent. The API 1312 can refer to a complete interface, a single function, or a set of APIs.

The service layer 1313 can provide software services to the computer 1302 and other components (whether illustrated or not) that are communicably coupled to the computer 1302. The functionality of the computer 1302 can be accessible for all service consumers using this service layer. Software services, such as those provided by the service layer 1313, can provide reusable, defined functionalities through a defined interface. For example, the interface can be software written in JAVA, C++, or a language providing data in extensible markup language (XML) format. While illustrated as an integrated component of the computer 1302, in alternative implementations, the API 1312 or the service layer 1313 can be stand-alone components in relation to other components of the computer 1302 and other components communicably coupled to the computer 1302. Moreover, any or all parts of the API 1312 or the service layer 1313 can be implemented as child or sub-modules of another software module, enterprise application, or hardware module without departing from the scope of the present disclosure.

The computer 1302 includes an interface 1304. Although illustrated as a single interface 1304 in FIG. 13, two or more interfaces 1304 can be used according to particular needs, desires, or particular implementations of the computer 1302 and the described functionality. The interface 1304 can be used by the computer 1302 for communicating with other systems that are connected to the network 1330 (whether illustrated or not) in a distributed environment. Generally, the interface 1304 can include, or be implemented using, logic encoded in software or hardware (or a combination of software and hardware) operable to communicate with the network 1330. More specifically, the interface 1304 can include software supporting one or more communication protocols associated with communications. As such, the network 1330 or the interface's hardware can be operable to communicate physical signals within and outside of the illustrated computer 1302.

The computer 1302 includes a processor 1305. Although illustrated as a single processor 1305 in FIG. 13, two or more processors 1305 can be used according to particular needs, desires, or particular implementations of the computer 1302 and the described functionality. Generally, the processor 1305 can execute instructions and can manipulate data to perform the operations of the computer 1302, including operations using algorithms, methods, functions, processes, flows, and procedures as described in the present disclosure.

The computer 1302 also includes a database 1306 that can hold data for the computer 1302 and other components connected to the network 1330 (whether illustrated or not). For example, database 1306 can be an in-memory, conventional, or a database storing data consistent with the present disclosure. In some implementations, database 1306 can be a combination of two or more different database types (for example, hybrid in-memory and conventional databases) according to particular needs, desires, or particular implementations of the computer 1302 and the described functionality. Although illustrated as a single database 1306 in FIG. 13, two or more databases (of the same, different, or combination of types) can be used according to particular needs, desires, or particular implementations of the computer 1302 and the described functionality. While database 1306 is illustrated as an internal component of the computer 1302, in alternative implementations, database 1306 can be external to the computer 1302.

The computer 1302 also includes a memory 1307 that can hold data for the computer 1302 or a combination of components connected to the network 1330 (whether illustrated or not). Memory 1307 can store any data consistent with the present disclosure. In some implementations, memory 1307 can be a combination of two or more different types of memory (for example, a combination of semiconductor and magnetic storage) according to particular needs, desires, or particular implementations of the computer 1302 and the described functionality. Although illustrated as a single memory 1307 in FIG. 13, two or more memories 1307 (of the same, different, or combination of types) can be used according to particular needs, desires, or particular implementations of the computer 1302 and the described functionality. While memory 1307 is illustrated as an internal component of the computer 1302, in alternative implementations, memory 1307 can be external to the computer 1302.

The application 1308 can be an algorithmic software engine providing functionality according to particular needs, desires, or particular implementations of the computer 1302 and the described functionality. For example, application 1308 can serve as one or more components, modules, or applications. Further, although illustrated as a single application 1308, the application 1308 can be implemented as multiple applications 1308 on the computer 1302. In addition, although illustrated as internal to the computer 1302, in alternative implementations, the application 1308 can be external to the computer 1302.

The computer 1302 can also include a power supply 1314. The power supply 1314 can include a rechargeable or non-rechargeable battery that can be configured to be either user- or non-user-replaceable. In some implementations, the power supply 1314 can include power-conversion and management circuits, including recharging, standby, and power management functionalities. In some implementations, the power supply 1314 can include a power plug to allow the computer 1302 to be plugged into a wall socket or a power source to, for example, power the computer 1302 or recharge a rechargeable battery.

There can be any number of computers 1302 associated with, or external to, a computer system containing computer 1302, with each computer 1302 communicating over network 1330. Further, the terms “client,” “user,” and other appropriate terminology can be used interchangeably, as appropriate, without departing from the scope of the present disclosure. Moreover, the present disclosure contemplates that many users can use one computer 1302 and one user can use multiple computers 1302.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. For example, the signal can be a machine-generated electrical, optical, or electromagnetic signal that is generated to encode information for transmission to a suitable receiver apparatus for execution by a data processing apparatus. The computer-storage medium can be a machine-readable storage device, a machine-readable storage substrate, a random or serial access memory device, or a combination of computer-storage mediums.

The terms “data processing apparatus,” “computer,” and “electronic computer device” (or equivalent as understood by one of ordinary skill in the art) refer to data processing hardware. For example, a data processing apparatus can encompass all kinds of apparatuses, devices, and machines for processing data, including by way of example, a programmable processor, a computer, or multiple processors or computers. The apparatus can also include special purpose logic circuitry including, for example, a central processing unit (CPU), a field-programmable gate array (FPGA), or an application-specific integrated circuit (ASIC). In some implementations, the data processing apparatus or special purpose logic circuitry (or a combination of the data processing apparatus or special purpose logic circuitry) can be hardware- or software-based (or a combination of both hardware- and software-based). The apparatus can optionally include code that creates an execution environment for computer programs, for example, code that constitutes processor firmware, a protocol stack, a database management system, an operating system, or a combination of execution environments. The present disclosure contemplates the use of data processing apparatuses with or without conventional operating systems, such as LINUX, UNIX, WINDOWS, MAC OS, ANDROID, or IOS.

A computer program, which can also be referred to or described as a program, software, a software application, a module, a software module, a script, or code, can be written in any form of programming language. Programming languages can include, for example, compiled languages, interpreted languages, declarative languages, or procedural languages. Programs can be deployed in any form, including as stand-alone programs, modules, components, subroutines, or units for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files storing one or more modules, sub-programs, or portions of code. A computer program can be deployed for execution on one computer or on multiple computers that are located, for example, at one site or distributed across multiple sites that are interconnected by a communication network. While portions of the programs illustrated in the various figures may be shown as individual modules that implement the various features and functionality through various objects, methods, or processes, the programs can instead include a number of sub-modules, third-party services, components, and libraries. Conversely, the features and functionality of various components can be combined into single components as appropriate. Thresholds used to make computational determinations can be statically, dynamically, or both statically and dynamically determined.

The methods, processes, or logic flows described in this specification can be performed by one or more programmable computers executing one or more computer programs to perform functions by operating on input data and generating output. The methods, processes, or logic flows can also be performed by, and apparatus can also be implemented as, special purpose logic circuitry, for example, a CPU, an FPGA, or an ASIC.

Computers suitable for the execution of a computer program can be based on one or more of general and special purpose microprocessors and other kinds of CPUs. The elements of a computer are a CPU for performing or executing instructions and one or more memory devices for storing instructions and data. Generally, a CPU can receive instructions and data from (and write data to) a memory.

Graphics processing units (GPUs) can also be used in combination with CPUs. The GPUs can provide specialized processing that occurs in parallel to processing performed by CPUs. The specialized processing can include artificial intelligence (AI) applications and processing, for example. GPUs can be used in GPU clusters or in multi-GPU computing.

A computer can include, or be operatively coupled to, one or more mass storage devices for storing data. In some implementations, a computer can receive data from, and transfer data to, the mass storage devices including, for example, magnetic, magneto-optical disks, or optical disks. Moreover, a computer can be embedded in another device, for example, a mobile telephone, a personal digital assistant (PDA), a mobile audio or video player, a game console, a global positioning system (GPS) receiver, or a portable storage device such as a universal serial bus (USB) flash drive.

Computer-readable media (transitory or non-transitory, as appropriate) suitable for storing computer program instructions and data can include all forms of permanent/non-permanent and volatile/non-volatile memory, media, and memory devices. Computer-readable media can include, for example, semiconductor memory devices such as random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices. Computer-readable media can also include, for example, magnetic devices such as tape, cartridges, cassettes, and internal/removable disks. Computer-readable media can also include magneto-optical disks and optical memory devices and technologies including, for example, digital video disc (DVD), CD-ROM, DVD+/−R, DVD-RAM, DVD-ROM, HD-DVD, and BLU-RAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated into, special purpose logic circuitry.

Implementations of the subject matter described in the present disclosure can be implemented on a computer having a display device for providing interaction with a user, including displaying information to (and receiving input from) the user. Types of display devices can include, for example, a cathode ray tube (CRT), a liquid crystal display (LCD), a light-emitting diode (LED), and a plasma monitor. Display devices can include a keyboard and pointing devices including, for example, a mouse, a trackball, or a trackpad. User input can also be provided to the computer through the use of a touchscreen, such as a tablet computer surface with pressure sensitivity or a multi-touch screen using capacitive or electric sensing. Other kinds of devices can be used to provide for interaction with a user, including to receive user feedback including, for example, sensory feedback including visual feedback, auditory feedback, or tactile feedback. Input from the user can be received in the form of acoustic, speech, or tactile input. In addition, a computer can interact with a user by sending documents to, and receiving documents from, a device that the user uses. For example, the computer can send web pages to a web browser on a user's client device in response to requests received from the web browser.

The term “graphical user interface,” or “GUI,” can be used in the singular or the plural to describe one or more graphical user interfaces and each of the displays of a particular graphical user interface. Therefore, a GUI can represent any graphical user interface, including, but not limited to, a web browser, a touch-screen, or a command line interface (CLI) that processes information and efficiently presents the information results to the user. In general, a GUI can include a plurality of UI elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server. Moreover, the computing system can include a front-end component, for example, a client computer having one or both of a graphical user interface or a Web browser through which a user can interact with the computer. The components of the system can be interconnected by any form or medium of wireline or wireless digital data communication (or a combination of data communication) in a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) (for example, using 802.11 a/b/g/n or 802.20 or a combination of protocols), all or a portion of the Internet, or any other communication system or systems at one or more locations (or a combination of communication networks). The network can communicate with, for example, Internet Protocol (IP) packets, frame relay frames, asynchronous transfer mode (ATM) cells, voice, video, data, or a combination of communication types between network addresses.

The computing system can include clients and servers. A client and server can generally be remote from each other and can typically interact through a communication network. The relationship of client and server can arise by virtue of computer programs running on the respective computers and having a client-server relationship.

Cluster file systems can be any file system type accessible from multiple servers for read and update. Locking or consistency tracking may not be necessary since the locking of exchange file system can be done at application layer. Furthermore, Unicode data files can be different from non-Unicode data files.

While this specification contains many specific implementation details, these should not be construed as limitations on the scope of what may be claimed, but rather as descriptions of features that may be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional), to achieve desirable results. In certain circumstances, multitasking or parallel processing (or a combination of multitasking and parallel processing) may be advantageous and performed as deemed appropriate.

Moreover, the separation or integration of various system modules and components in the previously described implementations should not be understood as requiring such separation or integration in all implementations. It should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

Furthermore, any claimed implementation is considered to be applicable to at least a computer-implemented method; a non-transitory, computer-readable medium storing computer-readable instructions to perform the computer-implemented method; and a computer system including a computer memory interoperably coupled with a hardware processor configured to perform the computer-implemented method or the instructions stored on the non-transitory, computer-readable medium.

What is claimed is:

1. A computer-implemented method for comprising:
identifying historical production data related to a plurality of previously-drilled wells;
determining, based on the historical production data, a correlation between productivity index and estimated ultimate recovery (EUR);
calculating a first productivity index for a current well; and
determining, based on the productivity index of the current well and the correlation, a first EUR of the current well.

2. The computer-implemented method of claim 1, wherein the first productivity index is an instantaneous productivity index value at a 30-day flowback time.

3. The computer-implemented method of claim 1, wherein the first productivity index is calculated using:
$$Productivity Index ( J ) = \frac{Q}{{P}_{e} - {P}_{w f}} ,$$
where J is the first productivity index in stock tank barrel/day/pound per square inch (STB/D/PSI), Q is a surface flowrate at standard conditions in STB/D, Pₑ is an external boundary radius pressure in PSI, and P_{wf} is a well sand-face mill-perf pressure in PSI.

4. The computer-implemented method of claim 1, wherein the historical data includes at least one of: historical EUR data of the plurality of previously-drilled wells or historical productivity index data of the plurality of previously-drilled wells.

5. The computer-implemented method of claim 1, further comprising:
operating the current well based on the first EUR.

6. The computer-implemented method of claim 1, wherein identifying, based on the historical production data, a correlation between productivity index and estimated ultimate recovery (EUR) comprises:
generating, using the historical production data, a numerical model for history matching and forecasting;
performing a probabilistic analysis using the numerical model to calculate a predicted EUR;
plotting historical productivity index data versus the predicted EUR; and
generating a best-fit linear line through the plotted data points.

7. The computer-implemented method of claim 6, wherein the probabilistic analysis is performed using a Monte Carlo simulation.

8. A computer-implemented method comprising:
identifying productivity index data associated with a well;
calculating, based on the productivity index data, an estimated ultimate recovery (EUR) of the well; and
operating the well based on the predicted EUR of the well.

9. The computer-implemented method of claim 8, further comprising:
calculating the EUR of the well based on a correlation of historical productivity index data of at least one other well and a historical EUR of the at least one other well.

10. The computer-implemented method of claim 9, wherein the correlation is a linear correlation.

11. The computer-implemented method of claim 8, wherein the productivity index data is based on less than five weeks of gas flowback data of the well.

12. The computer-implemented method of claim 8, wherein the productivity index is calculated using:
$$Productivity Index ( J ) = \frac{Q}{{P}_{e} - {P}_{w f}} ,$$
where J is the first productivity index in stock tank barrel/day/pound per square inch (STB/D/PSI), Q is a surface flowrate at standard conditions in STB/D, Pₑ is an external boundary radius pressure in PSI, and P_{wf} is a well sand-face mid-perf pressure in PSI.

13. The computer-implemented method of claim 8, wherein the productivity index is an instantaneous productivity index value at a 30-day flowback time.

14. A system comprising:
one or more processors configured to perform operations comprising:
identifying historical production data related to a plurality of previously-drilled wells;
determining, based on the historical production data, a correlation between productivity index and estimated ultimate recovery (EUR);
calculating a first productivity index for a current well; and
determining, based on the productivity index of the current well and the correlation, a first EUR of the current well.

15. The system of claim 14, wherein the first productivity index is an instantaneous productivity index value at a 30-day flowback time.

16. The system of claim 14, wherein the first productivity index is calculated using:
$$Productivity Index ( J ) = \frac{Q}{{P}_{e} - {P}_{w f}} ,$$
where J is the first productivity index in stock tank barrel/day/pound per square inch (STB/D/PSI), Q is a surface flowrate at standard conditions in STB/D, Pₑ is an external boundary radius pressure in PSI, and P_{wf} is a well sand-face mid-perf pressure in PSI.

17. The system of claim 14, wherein the historical data includes at least one of: historical EUR data of the plurality of previously-drilled wells or historical productivity index data of the plurality of previously-drilled wells.

18. The system of claim 14, the operations further comprising:
operating the current well based on the first EUR.

19. The system of claim 14, wherein identifying, based on the historical production data, a correlation between productivity index and estimated ultimate recovery (EUR) comprises:
generating, using the historical production data, a numerical model for history matching and forecasting;
performing a probabilistic analysis using the numerical model to calculate a predicted EUR;
plotting historical productivity index data versus the predicted EUR; and
generating a best-fit linear line through the plotted data points.

20. The system of claim 19, wherein the probabilistic analysis is performed using a Monte Carlo simulation.
